(19) United States
(12) Patent Application Publication
(10) Pub. No.: US 2010/0203700 A1
(43) Pub. Date: Aug. 12, 2010

(54) METHOD OF FORMING SEMICONDUCTOR DEVICE

(76) Inventors: Kyungmun Byun, Seoul (KR); Deok-Young Jung, Seoul (KR); Ju-Seon Goo, Suwon-si (KR); Eunkee Hong, Sungnam-Shi (KR)

Correspondence Address: MYERS BIGEL SIBLEY & SAJOVEC, PO BOX 37428, RALEIGH, NC, 27627, US

(21) Appl. No.: 12/686,638

(22) Filed: Jan. 13, 2010

(30) Foreign Application Priority Data
Feb. 6, 2009 (KR) 10-20090009641

(51) Int. Cl. H01L 21/762

(52) U.S. Cl. 438/400; 257/E21.546

(57) ABSTRACT

A method of forming a semiconductor device includes preparing a substrate having a recessed area. A silicon oxide layer is formed at the recessed area. A catalytic nitridation treatment is performed for an upper portion of the silicon oxide layer to form a nitridation reactant on the upper portion of the silicon oxide layer. A dielectric layer is formed on the silicon oxide layer where the nitridation reactant is formed. The dielectric layer is annealed. According to the foregoing method, recession of the dielectric layer is prevented to fabricate a high-quality semiconductor device.

### CROSS-REFERENCE TO RELATED APPLICATIONS

This U.S. non-provisional patent application claims priority under 35 U.S.C. §119 to Korean Patent Application No. 10-2009-0009641, filed on Feb. 6, 2009, the entirety of which is hereby incorporated by reference.

### FIELD OF THE INVENTION

The present invention relates to methods of fabricating a semiconductor device and, more particularly, to a method of forming a dielectric layer of a semiconductor device.

### BACKGROUND OF THE INVENTION

It is desirable for semiconductor devices to become finer to achieve high integration and high performance. A shallow trench isolation (STI) manner has been used as an isolation manner of the semiconductor device. According to the STI manner, a gap-fill dielectric layer fills a trench formed on a semiconductor substrate to form a device isolation layer. However, etching resistance of the gap-fill dielectric layer filling the trench or a gap between finer patterns is often deteriorated.

### SUMMARY

Embodiments of the present invention provide a method of forming a semiconductor device. In some embodiments, the method may include preparing a substrate having a recessed area, forming a silicon oxide layer at the recessed area, performing a catalytic nitridation treatment for an upper portion of the silicon oxide layer to form a nitridation reactant on the upper portion of the silicon oxide layer, forming a dielectric layer on the silicon oxide layer where the nitridation reactant is formed, and annealing the dielectric layer.

In certain embodiments, the recessed area includes a trench or a gap between patterns.

In certain embodiments, the silicon oxide layer is formed to a thickness ranging from 20 to 150 angstroms.

In certain embodiments, the silicon oxide layer is deposited by either one of chemical vapor deposition (CVD) and atomic layer deposition (ALD).

In certain embodiments, the catalytic nitridation treatment includes a plasma treatment of a nitridation agent.

In certain embodiments, the nitridation agent contains amine, ammonia (NH3) or pyridine (C5H5N).

In certain embodiments, the catalytic nitridation treatment includes an annealing treatment of a nitridation agent.

In certain embodiments, the catalytic nitridation treatment includes a cleaning treatment using a solution containing ammonia water (NH3OH).

In certain embodiments, the dielectric layer contains a spin-on-glass (SOG) material.

In certain embodiments, the dielectric layer is annealed at a temperature ranging from 550 to 1,000 degrees centigrade.

### BRIEF DESCRIPTION OF THE DRAWINGS

FIGS. 1A to 1G are cross-sectional views illustrating a method of forming a semiconductor device according to some embodiments of the present invention.

FIGS. 2A to 2E are cross-sectional views illustrating a method of forming a semiconductor device according to other embodiments of the present invention.

FIG. 3 is a graph illustrating evaluation of characteristics based on a catalytic nitridation treatment according to embodiments of the present invention.

FIG. 4 is a block diagram of a memory system according to embodiments of the present invention.

### DETAILED DESCRIPTION OF THE INVENTION

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

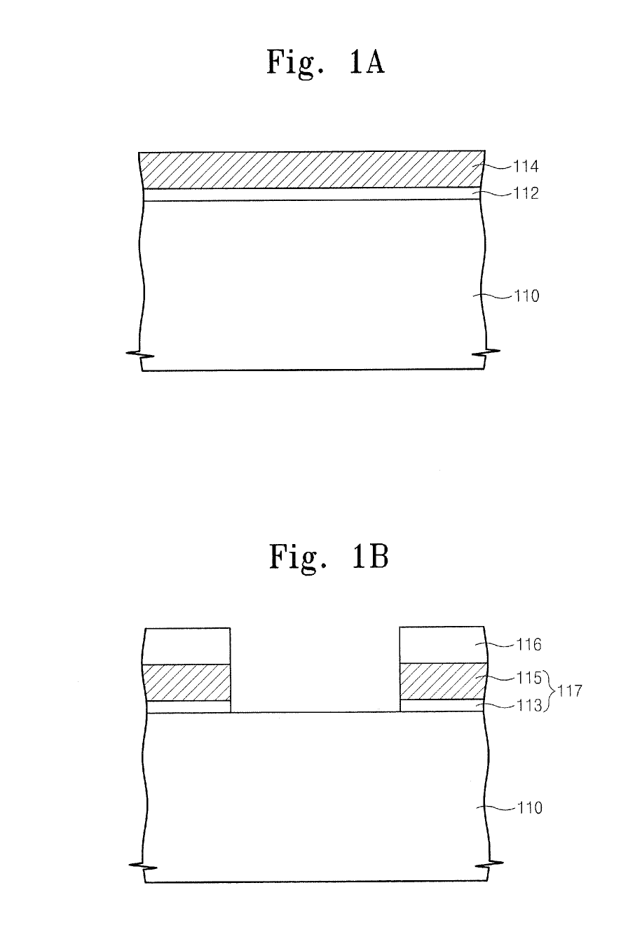

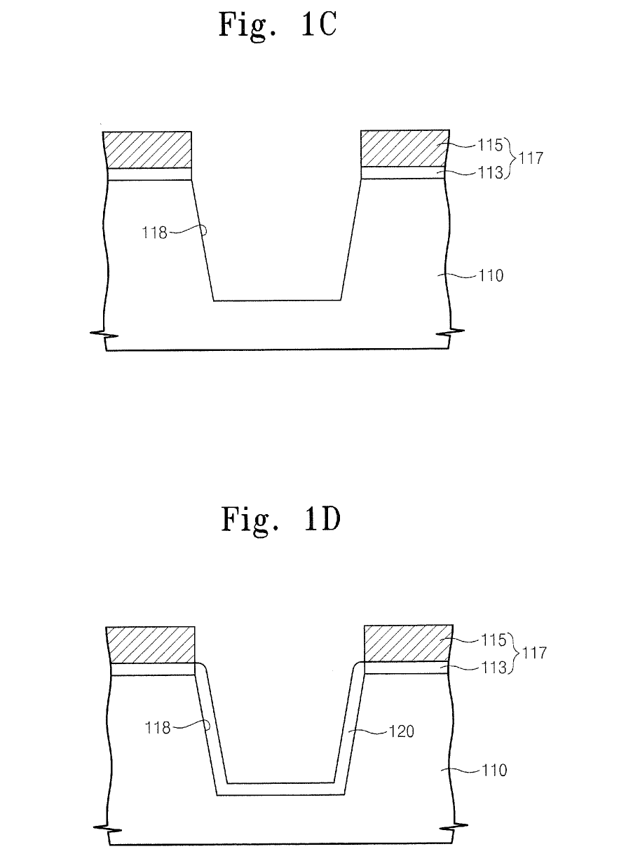

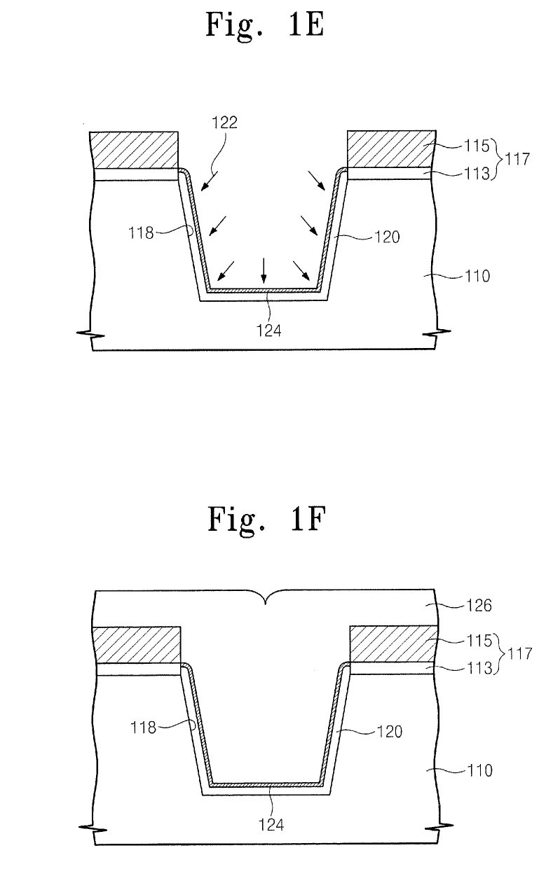

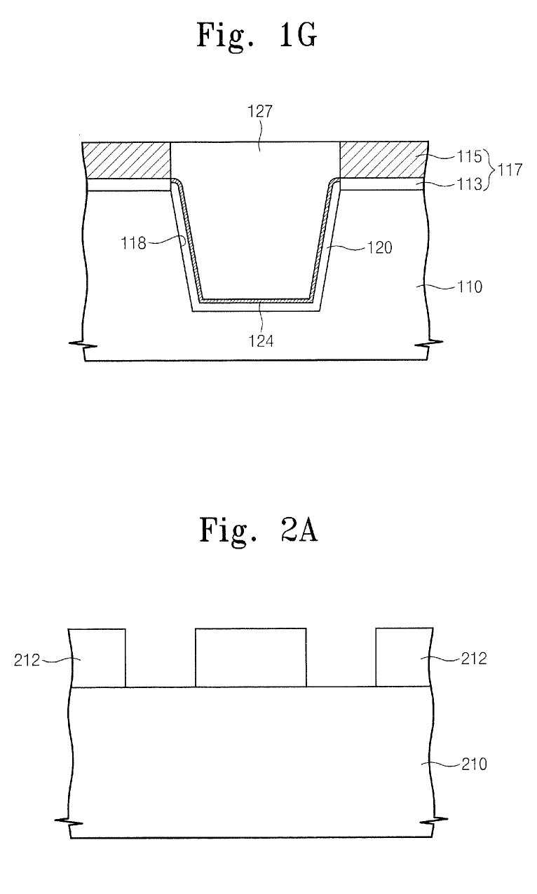

FIGS. 1A to 1G are cross-sectional views illustrating a method of forming a semiconductor device according to some embodiments of the present invention.

Referring to FIG. 1A, a pad oxide layer 112 and a mask layer 114 may be formed on a semiconductor substrate 110. The pad oxide layer 112 may be formed of silicon oxide. For instance, the pad oxide layer 112 may be formed to have a thickness ranging from 46 to 65 angstroms by thermally oxidizing the semiconductor substrate 110, for example, by heating at a temperature of 800 degrees centigrade. The mask layer 114 may be formed of silicon nitride or polysilicon. For instance, silicon nitride may be formed to have a thickness ranging from 800 to 1,500 angstroms by means of a diffusion process or a chemical vapor deposition (CVD) process. Since silicon oxide is not easily oxidized, it may be used as a mask to prevent oxidation of a surface of the semiconductor substrate 110. The pad oxide layer 112 may relax a stress generated at the boundary between the semiconductor substrate 110 and the mask layer 114, and thereby prevent dislocation caused by the stress propagating to the surface of the semiconductor substrate 110.

The semiconductor substrate 110 may be a single-crystalline bulk silicon substrate. Alternatively, the semiconductor substrate 110 may be a P-type semiconductor substrate doped with P-type impurities such as boron (B) or another type of a substrate. Because a method of forming a trench on a semiconductor substrate is just explained in this embodiment, the semiconductor substrate 110 is not limited to the above, and the selection of a suitable substrate will be within the skill of one in the art.

Referring to FIG. 1B, a photoresist pattern 116 is formed on the mask layer 114. The mask layer 114 and the pad oxide layer 112 are etched using the photoresist pattern 116 as a mask to form a mask pattern 117 for a trench. The mask pattern 117 may include a mask layer pattern 115 and a pad oxide pattern 113. Etching the mask layer 114 and the pad oxide layer 112 may be done by a dry etch.

Referring to FIG. 1C, following formation of the photoresist pattern 116, the semiconductor substrate 110 is etched using the mask pattern 117 as a mask to form a trench 118. For instance, the trench 118 may be formed to have a depth ranging from 3,500 to 4,500 angstroms by anisotropically etching the semiconductor substrate 110. Instead of the etching using the photoresist pattern 117 as a mask, the mask pattern 114, the pad oxide layer 112, and the semiconductor substrate 110 may be successively etched using the photoresist pattern 116 to form a trench 118.

Referring to FIG. 1D, following formation of the trench 118, a silicon oxide layer 120 is formed on an inner wall of the trench 118. The silicon oxide layer 120 may be formed by means of chemical vapor deposition (CVD) or atomic layer deposition (ALD). The silicon oxide layer 120 may be formed to a thickness ranging from 20 to 150 angstroms.

Referring to FIG. 1E, the inner wall including the silicon oxide layer 120 is subjected to a catalytic nitridation treatment 122 to form a nitridation reactant 124. The catalytic nitridation treatment 122 may include a plasma treatment of a nitridation agent, an annealing treatment using a nitridation agent or a cleaning treatment using a solution containing ammonia water (NH₄OH). For instance, the nitridation agent may include amine, ammonia (NH₃) or pyridine (C₅H₅N). The plasma treatment of a nitridation agent may be a plasma treatment of ammonia gas. The nitridation reactant 124 may be formed by reacting Si—H and Si—OH of an upper portion of the silicon oxide layer 120 to NH₃. Generation of the nitridation reactant 124 may include a reaction as follows:

Si—H+NH3→SiNH₂+H₂

Si—OH+NH₃→H₂O

The nitridation reactant 124 is formed on the inner wall of the trench 118 by the catalytic nitridation treatment 122. The nitridation reactant 124 formed on the inner wall of the trench 118 may be SiNH₂.

Referring to FIG. 1F, a gap-fill dielectric layer 126 is formed on a semiconductor substrate 110 including the trench 118. For instance, the gap-fill dielectric layer 126 may be formed by means of a spin-on-glass (SOG) process. Specifically, the gap-fill dielectric layer 126 may be formed by means of an SOG process using polysilanzane-based SOG. The gap-fill dielectric layer 126 may be annealed at a temperature ranging from 550 to 1,000 degrees centigrade. In the case where the nitridation reactant 124 may be SiNH₂, a non-bonding electron pair of nitrogen (N) and hydrogen (H) of Si—II in the gap-fill dielectric layer 126 may form a hydrogen bond. The hydrogen bond may weaken a bonding force of Si—H in the gap-fill dielectric layer 126. As a result, silicon of the gap-fill dielectric layer 126 may bond to external oxygen (O₂) or vapor (H₂O) to form Si—O. For this reason, etching resistance of the gap-fill dielectric layer 126 may be improved.

Referring to FIG. 1G, the gap-fill dielectric layer 126 is etched to form a device isolation layer 127. Etching the gap-fill dielectric layer 126 may include a planarization process which is performed using the mask pattern 117 as an etch mask by means of chemical mechanical polishing (CMP). The device isolation layer 127 may define an active region. Because cleaning and wet-etching resistances of the device isolation layer 127 are improved and recession of the device isolation layer 127 is prevented, a high-quality semiconductor device may be provided.

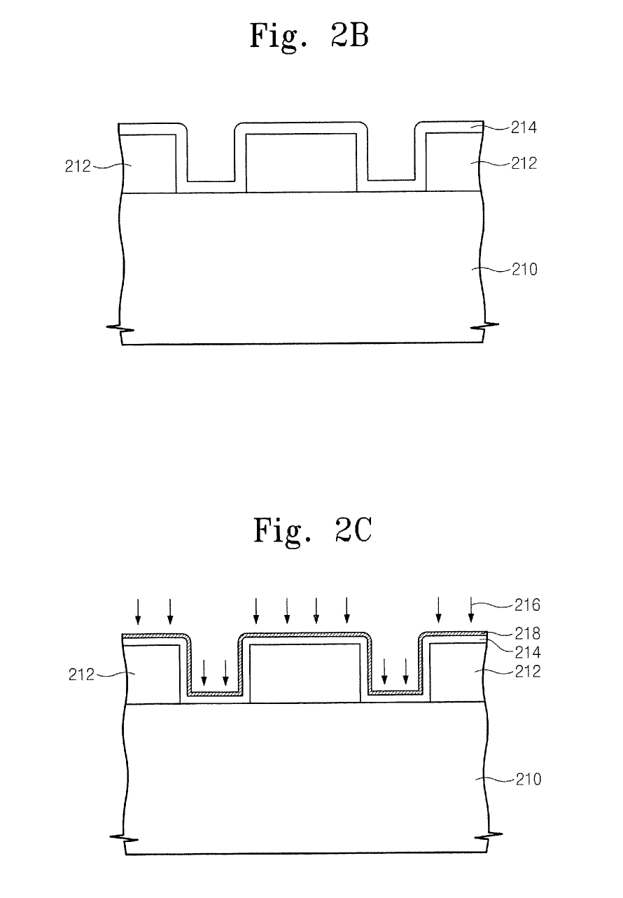

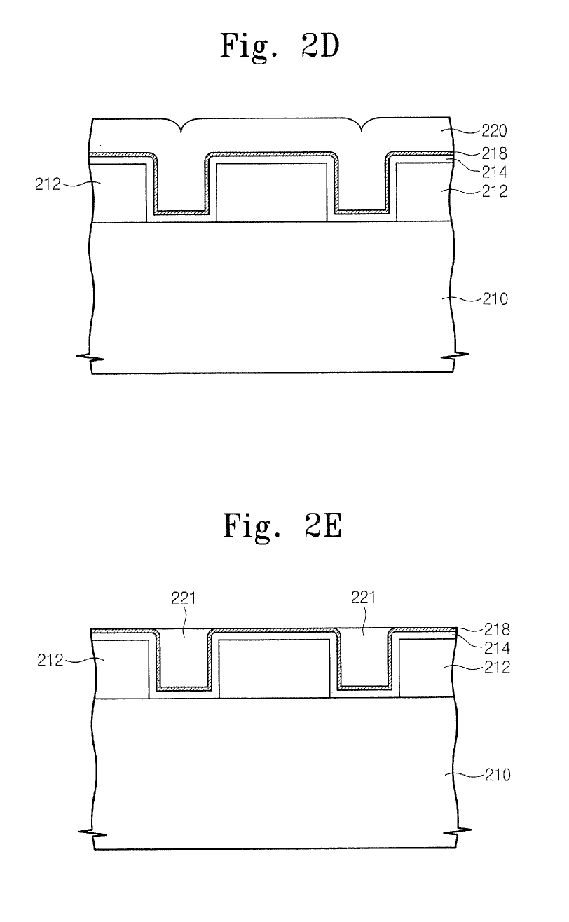

FIGS. 2A to 2G are cross-sectional views illustrating a method of forming a semiconductor device according to other embodiments of the present invention. Similar processes to those explained in FIGS. 1A to 1G will not be explained again.

Referring to FIG. 2A, a semiconductor device (not shown) is formed on a semiconductor substrate 210. A pattern 212 is formed on the semiconductor substrate 210 where the semiconductor device is formed. The pattern 212 may include a metal interconnection.

Referring to FIG. 2B, a silicon oxide layer 214 is formed on the semiconductor substrate 210 where the pattern 212 is formed. The silicon oxide layer 214 may be formed by means of chemical vapor deposition (CVD) or atomic layer deposition (ALD). The silicon oxide layer 214 may be formed to a thickness ranging from 20 to 150 angstroms.

Referring to FIG. 2C, an upper portion of the silicon oxide layer 214 is subjected to a catalytic nitridation treatment 216 to form a nitridation reactant 218. The catalytic nitridation treatment 216 may include a plasma treatment of a nitridation agent, an annealing treatment using a nitridation agent or a cleaning treatment using a solution containing ammonia water (NH₄OH). For instance, the nitridation agent may include amine, ammonia (NH₃) or pyridine (C₅H₅N). The plasma treatment of a nitridation agent may be a plasma treatment of ammonia gas. The nitridation reactant 218 may be formed by reacting Si—H and Si—OH of an upper portion of the silicon oxide layer 214 to NH₃. Generation of the nitridation reactant may include a reaction as follows:

Si—H+NH3→SiNH₂+H₂

Si—OH+NH₃→SiNH₂+H₂O

The nitridation reactant 218 is formed on the upper portion of the silicon oxide layer 214. The nitridation reactant 218 formed on the upper portion of the silicon oxide layer 214 may be SiNH₂.

Referring to FIG. 2D, a dielectric layer 220 is formed on the silicon oxide layer 214 where the nitridation reactant 218 is formed. The dielectric layer 220 may be formed by means of a spin-on-glass (SOG) process. Specifically, the dielectric layer 220 may be formed by means of an SOG process using polysilazane-based SOG. The dielectric layer 220 may be annealed at a temperature ranging from 550 to 1,000 degrees centigrade. In the case where the nitridation reactant 218 may be SiNH₂, a non-bonding electron pair of nitrogen (N) and hydrogen (H) of Si—H in the dielectric layer 220 may form a hydrogen bond. The hydrogen bond may weaken a bonding force of Si—H in the dielectric layer 220. As a result, silicon of the dielectric layer 220 may bond to external oxygen (O₂) or vapor (H₂O) to form Si—O. For this reason, etching resistance of the dielectric layer 220 may be improved.

Referring to FIG. 2E, the dielectric layer 220 is etched. Etching the dielectric layer 220 may include a planarization process which is performed by means of chemical mechanical polishing (CMP). Because cleaning and wet-etching resistances of the dielectric pattern 221 are improved and recession of the dielectric pattern 221 is prevented, a high-quality semiconductor device may be provided.

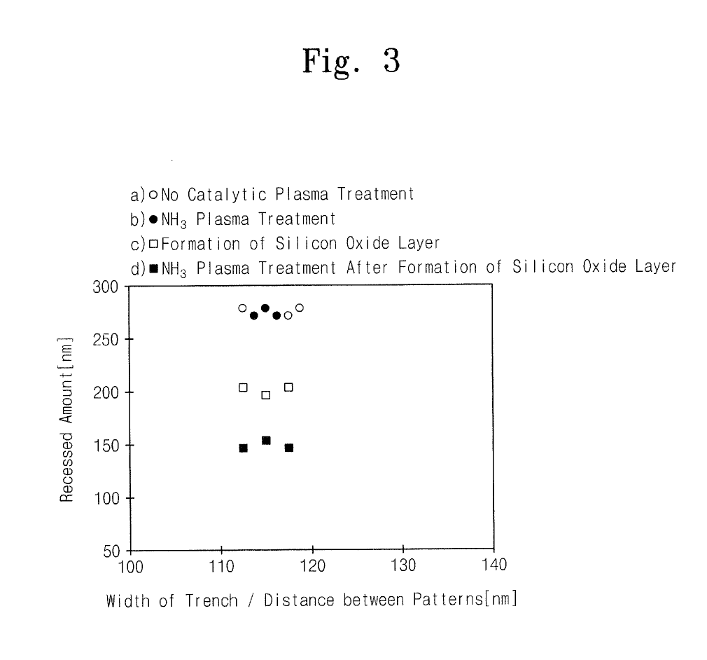

FIG. 3 is a graph illustrating evaluation of characteristics based on a catalytic nitridation treatment according to embodiments of the present invention.

Referring to FIG. 3, characteristics based on a catalytic nitridation treatment according to embodiments of the present invention were evaluated. A wet etch was conducted using LAL500 for 30 seconds. In FIG. 3, the x-axis denotes width of a trench or distance between patterns and the y-axis denotes the recessed amount. In the case where a catalytic nitridation treatment is not performed (CASE (a)), the recessed amount was about 270 nanometers. In the case where an NH₃ plasma treatment is performed (CASE (b)), the recessed amount was about 270 nanometers. In the case where only a silicon oxide layer is formed (CASE (c)), the recessed amount was about 200 nanometers. In the case where a catalytic nitridation treatment is performed to form a nitridation reactant after forming a silicon oxide layer on an inner wall of a trench, the recessed amount was about 150 nanometers. In conclusion, the recessed amount was smallest in CASE (d).

A semiconductor device is formed by means of the above-described methods according to embodiments of the present invention to provide a high-quality semiconductor device.

To sum up, nitrogen (N) and hydrogen (H) of a nitridation agent may react to silicon compounds (Si—OH or Si—O) on a silicon oxide layer to form a SiNₓH_{y} type compound. The SiNₓH_{y} may weaken a bonding force of Si—H of a dielectric layer formed on the silicon oxide layer and may act as a catalyst helping silicon of the dielectric layer bond to external oxygen (O₂) or vapor (H₂O). As a result, the Si of the dielectric layer may form Si—O and etching resistance of the dielectric layer may be improved.

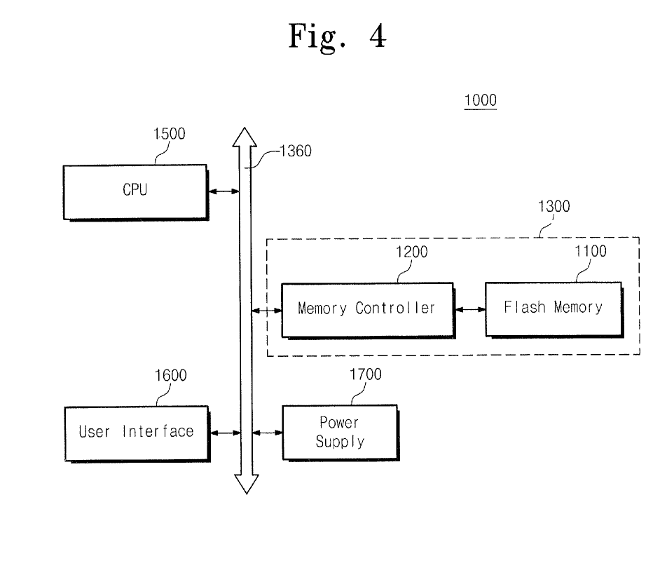

FIG. 4 is a block diagram of a memory system according to embodiments of the present invention.

Referring to FIG. 4, a memory system 1000 includes a semiconductor memory device 1300 including a memory device 1100 and a memory controller 1200, a central processing unit (CPU) 1500 electrically connected to a system bus 1450, a user interface 1600, and a power supply 1700.

Data provided through the user interface 1600 or data processed by the CPU 1500 is stored in the memory device 1100 via the memory controller 1200. The memory device 1100 may include a solid-state disk/drive (SSD). In this case, write speed of the memory system 1000 may be improved dramatically. A semiconductor device according to embodiments of the present invention may be applied to the memory device 1100, the memory controller 1200, and the CPU 1500 which are set forth above.

Although not shown in the figure, it will be understood by a person of ordinary skill in the art that the memory system 1000 according to the present invention may be provided with an application chipset, a camera image processor (CIS), a mobile DRAM, and so forth.

Moreover, the memory system 1000 may be applied to personal digital assistants (PDAs), portable computers, web tablets, wireless phones, mobile phones, digital music players, memory cards or all devices capable of transmitting and/or receiving information in a wireless environment.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the invention.

What is claimed is:

1. A method of forming a semiconductor device, comprising:
preparing a substrate having a recessed area;
forming a silicon oxide layer at the recessed area;
performing a catalytic nitridation treatment for an upper portion of the silicon oxide layer to form a nitridation reactant on the upper portion of the silicon oxide layer;
forming a dielectric layer on the silicon oxide layer where the nitridation reactant is formed; and
annealing the dielectric layer.

2. The method as set forth in claim 1, wherein the recessed area includes a trench or a gap between patterns.

3. The method as set forth in claim 1, wherein the silicon oxide layer is formed to a thickness ranging from 20 to 150 angstroms.

4. The method as set forth in claim 1, wherein the silicon oxide layer is deposited by either one of chemical vapor deposition (CVD) and atomic layer deposition (ALD).

5. The method as set forth in claim 1, wherein the catalytic nitridation treatment includes a plasma treatment of a nitridation agent.

6. The method as set forth in claim 5, wherein the nitridation agent contains amine, ammonia (NH₃) or pyridine (C₅H₅N).

7. The method as set forth in claim 1, wherein the catalytic nitridation treatment includes an annealing treatment of a nitridation agent.

8. The method as set forth in claim 1, wherein the catalytic nitridation treatment includes a cleaning treatment using a solution containing ammonia water (NH₃OH).

9. The method as set forth in claim 1, wherein the dielectric layer contains a spin-on-glass (SOG) material.

10. The method as set forth in claim 1, wherein the dielectric layer is annealed at a temperature ranging from 550 to 1,000 degrees centigrade.

11. The method as set forth in claim 1, further including etching the annealed dielectric layer to form a device isolation layer.

12. The method as set forth in claim 11, wherein the etching includes a planarization process by means of chemical and mechanical polishing (CMP).
